(19) United States
(12) Patent Application Publication
(10) Pub. No.: US 2002/0095685 A1
(43) Pub. Date: Jul. 18, 2002

(54) Transponder for monitoring network elements in hybrid fiber coax networks

(76) Inventors: Heribert Baldus, Aachen (DE); Wolfgang Otto Budde, Aachen (DE); Karin Klabunde, Aachen (DE); Oliver Muelhens, Aachen (DE)

Correspondence Address: U.S. Philips Corporation, 580 White Plains Road, Tarrytown, NY, 10591, US

(21) Appl. No.: 10/043,523

(22) Filed: Jan. 11, 2002

(30) Foreign Application Priority Data
Jan. 13, 2001 (DE) 10101331.0

(51) Int. Cl. H04N 7/173; H04L 1/22; H04B 1/74; H02H 3/05; H05K 10/00; H03K 19/003

(52) U.S. Cl. 725/107; 725/129; 714/25

(57) ABSTRACT

The invention relates to a transponder for monitoring network elements of a hybrid fiber coax network with firmware, which firmware

comprise several overlaid layers (2, 12, 22) containing several software components known as function modules (3 to11, 13 to 19),

where a bottom layer (2) contains the function modules (3 to 11) which describe the functionality of the hardware components of the transponder,

and the function modules (13 to 19) of the layer (12) lying above the bottom layer (2) jointly form an application interface which can process the application software of the various manufacturer-dependent central monitoring systems, and hence the same transponder can be used in different monitoring systems with different protocols and administrative purposes.

The invention relates to a transponder with layered firmware.

A hybrid fiber coax network used as a broadband communication system with several network elements and users is disclosed by specification U.S. Pat. No. 5,854,703. The document describes the communication and transfer of communication signals controlled by an element control manager.

The invention is based on the object of producing a uniform software interface for transponders.

The object is achieved by a transponder of the type described in the opening paragraph in that the firmware of the transponder

comprises of several overlaid layers containing several software components known as function modules,

where a lower layer contains the function modules which describe the functionality of the hardware components of the transponder,

and the function modules of the layer lying above the bottom layer (2) jointly form an application interface which can process an application software of various manufacturer-dependent central monitoring systems, and hence the same transponder can be used in different monitoring systems with different protocols and management purposes.

For monitoring and management of network elements in a network e.g. hybrid fiber coax (HFC) network, a transponder is integrated in each network element. This transponder communicates with a central monitoring system via a bi-directional high frequency channel provided by the HFC network, in order to transmit measurement values or detect and diagnose critical situations.

For production of a transponder with an application interface, which allows the performance of various protocols and management applications for monitoring systems from various manufacturers, the firmware of the transponder is divided into layers. The bottom layer of the firmware rests on the transponder hardware. The bottom layer contains software components known as function modules which software components describe the functionality of the hardware components and offer defined software access to the hardware components. All function modules of the layer above together form an application interface used to perform specific applications from various manufacturers. These function modules can access other function modules both within their layer and on the layer below. On the application interface is a layer consisting of application programs.

The application programs for the various manufacturer-dependent monitoring systems are performed using the functions of the application interface. Consequently, different protocols and management applications can be used in the communication of the transponder and monitoring and management can individually be adapted to the individual network elements.

The function modules can be replaced in a specific fashion according to their functionality. In this way new software versions can be integrated by exchanging corresponding parts of the firmware in the transponder.

Access to the function modules of the layers is divided into two access levels. One level allows the supplier of the central monitoring system access to the application programs lying above the application interface, and the second level allows the manufacturer of the transponder access to the two layers lying below the application layer. By dividing the access into two it can be ensured that only the manufacturer of the transponder can modify the layers lying below the application interface.

By structuring the software in the form of layers, the internal structure of the transponder is hidden from the supplier or application developer of the HFC network as the supplier or application developer only has access to the application interface.

Another possibility of technical adaptation of the transponder is to exchange the basic hardware. The function modules of the bottom layer can be replaced while the function modules of the layer above and the application program can be used further unchanged.

The invention will be further described with reference to examples of embodiments shown in the drawings to which, however, the invention is not restricted. These show in:

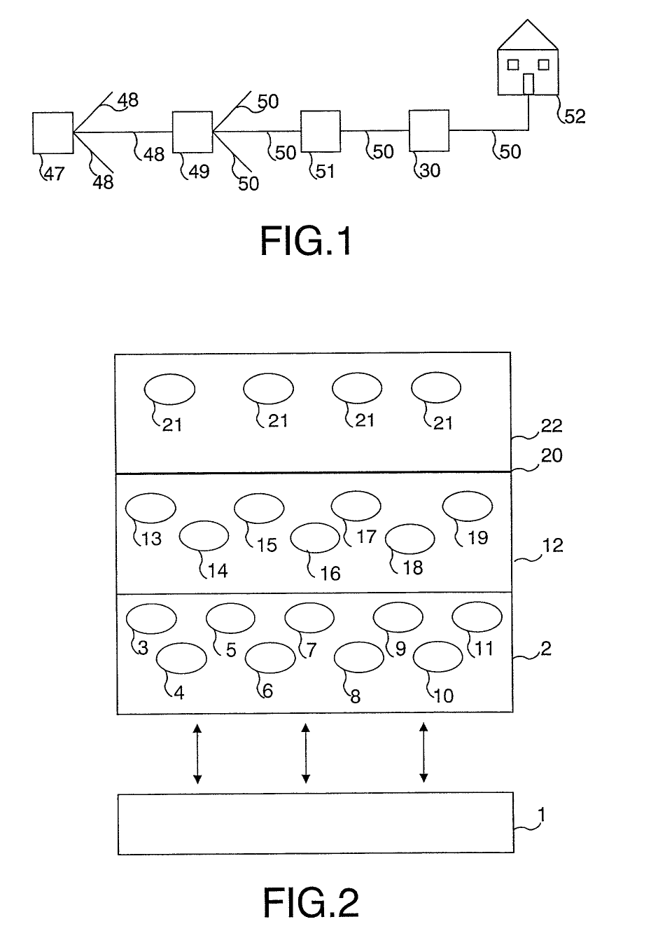

FIG. 1 a branch of the HFC network,

FIG. 2 a diagram of layered firmware

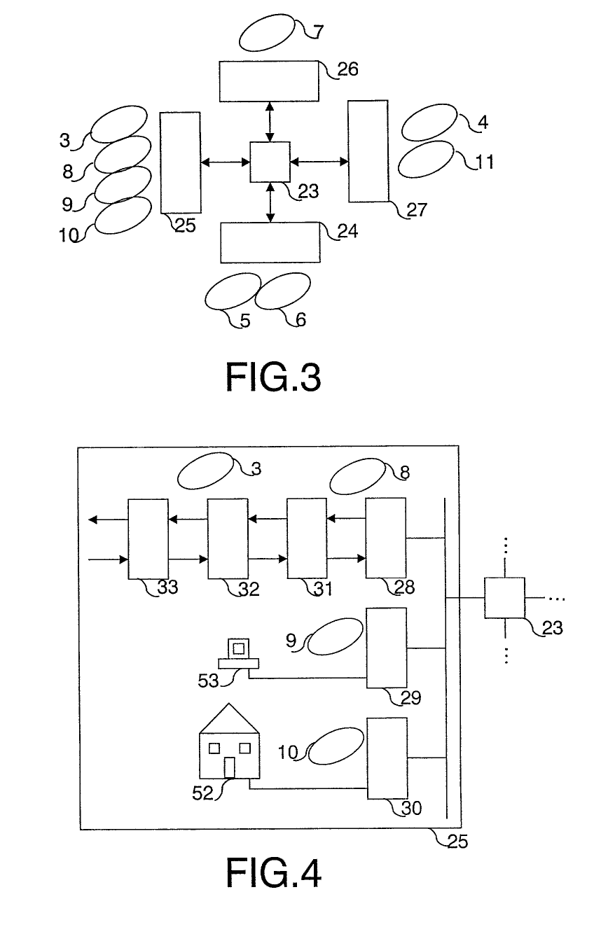

FIG. 3 a view of the hardware components and the associated software components of the bottom layer,

FIG. 4 a structure of the communication system,

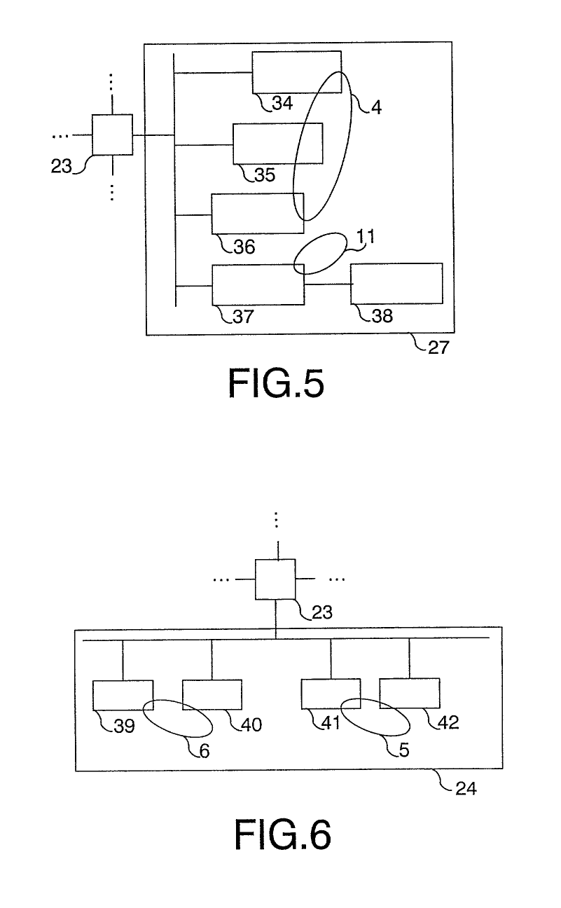

FIG. 5 a structure of the input and output system,

FIG. 6 a structure of the control system,

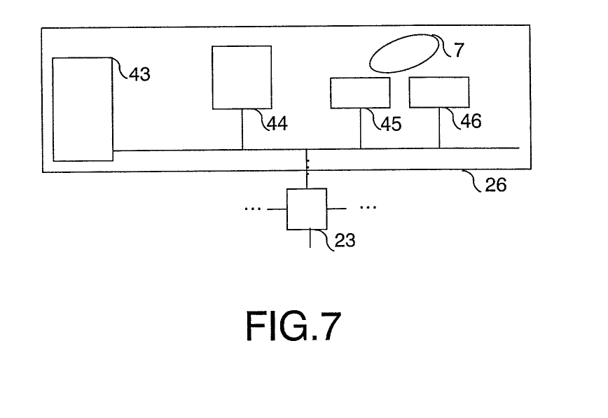

FIG. 7 a structure of the memory system.

A hybrid fiber coax network can serve not only as a cable TV network but also to transmit interactive services such as internet access, telephony and video-on-demand. These services require a high degree of reliability so a central monitoring system is required for the network and its network elements.

FIG. 1 shows a branch of a hybrid fiber coax (HFC) network which can connect together up to around 10,000 different network elements. Network elements of an HFC network can be high frequency amplifiers, transceivers, optical branch nodes, adapters (line extenders), power supply units. A transponder is integrated into each network element to monitor and manage the network elements which transponder together with the remote central monitoring system ensures the functionality and reliability of the network. The network branching shown in this example comprises a transceiver 47 connected via a hybrid fiber coax cable 48 with further network elements. The next network element for branching can be an optical branch point 49, the copper cable connections 50 of which lead via an amplifier 51 and a plug connector 30 to the end user 52.

The transponder with its hardware and software is described with reference to the further Figures. FIG. 2 shows the structure of the transponder firmware. The following layers were developed for the functionality of the transponder software.

A bottom lower layer 2 is placed on hardware 1 comprising several components. The components of hardware 1 are controlled by the bottom layer 2. The bottom layer 2 comprises several software components which fulfil different tasks on this layer.

In this example of embodiment the bottom layer 2 contains a software component referred to as RF interface 3, a software component referred to as measurement data interface 4, a software component referred to as control 5, a software component referred to as timer 6, a software component referred to as memory interface 7, a software component referred to as data buffer 8, a software component referred to as interface 9 for local access, a software component referred to as plug connection control module 10 and a software component referred to as expansion unit 11.

A middle layer 12 lying over the bottom layer 2 offers an application interface for various application programs 21.

A monitoring module 13 in the middle layer 12 detects certain measurement data and a configuration module 14 ensures the necessary links between the software and hardware components. A software configuration and transfer module 15 is responsible for the current version and exchange of software. The transponder is checked by a test module 16 within the middle layer 12. External communication between the transponder and a network monitoring system requires a communication module 17. Local communication of the transponder with network elements takes place via a second communication module 18. An interface 19 to the plug connection control module 10 allows a remote central monitoring system to configure and control the plug connection 30 to the end user 52.

A top layer 22 contains the various manufacturer-specific application programs 21.

FIGS. 3 to 7 show the relations between the software components and the components of hardware 1.

FIG. 3 gives a general overview of the allocation of the transponder hardware 1 to the competent software components of the bottom layer 2.

A control system 24, a communication system 25, a memory system 26 and an input and output system 27 form as sub-systems with a microprocessor 23 the hardware 1 of the transponder. The hardware components referred to as sub-systems 24 to 27 are coupled to the microprocessor 23 and have access to this. The software component controller 5 and timer 6 are allocated to the control system 24. The hardware components of the communication system 25 are represented in software terms by the RF interface 3, data buffer 8, interface 9 for local access and plug connection control module 10. The memory system 26 is accessed by the software component memory interface 7, and software components measurement data interface 4 and expansion unit 11 are responsible for the input and output system 27.

The communication system 25 with associated software components is explained in more detail with reference to FIG. 4. The sub-system connected to the microprocessor 23 comprises of a message memory 28, a serial interface 29 for local service work of a network administrator 53 and a plug connection 30 to the end user 52. The plug connection control module 10 in software terms represents the plug connection 30 which serves as an interface to the end user 52. The message memory 28 is connected with a hardware component modem 31 and this in turn with an analog/digital and digital/analog converter 32. The final hardware component of the sub-system is a transmitter-receiver unit 33 coupled to the converter 32.

The transmitter-receiver unit 33 for high-frequency signals applies a received signal to the converter 32. These hardware components are supported in their function of signal processing by the RF interface 3. The converter 32 passes the signal on to a modem 31 which temporarily stores the signal in the hardware component message memory 28. The message memory 28 and modem 31 can be access through the software component data buffer. If a signal is to be sent, the message memory 28 receives corresponding commands from microprocessor 23 and the work processes of the hardware and software components described above take place in reverse order.

FIG. 5 shows the hardware components of the input and output system 27. The system 27 comprises an interface 34 for analog devices, a temperature sensor 35 and a digital interface 36, the functionalities of which are described by the software component measurement data interface 4. The input and output system 27 is extended by an extension 38 coupled to the microprocessor 23 via an extension interface 37. The extension interface 37, together with the software component extension unit 11, is responsible for the configuration (e.g. bit rate of a serial extension bus, input and output data).

If the temperature sensor 35 measures a temperature lying above the temperature limit, the temperature value is detected by the measurement data interface 4 and sent to the microprocessor 23 for further processing.

FIG. 6 gives the structure of the control system 24. Coupled to the microprocessor 23 as hardware components of the control system 24 are a timer unit 39 and a monitoring unit 40. Both hardware components are represented by the software component timer 6. Further hardware components of this sub-system are a supply controller 41 and an interrupt controller 42 which together are represented by the software component controller 5.

The monitoring unit 40 (watchdog) waits for a control signal sent by microprocessor 23 at certain time intervals determined by the timer 39. If in the event of a fault the watchdog no longer receives this control signals, the watchdog would trigger a restart of the transponder. The parameters and control functions necessary for this function are set by the software component timer 6. If an interruption occurs in the power supply or in the operation, this is handled by the hardware components supply controller 41, interrupt controller 42 and the software component controller 5. One possible measure of controller 5 can be to engage a save mode.

The memory system 26 shown in FIG. 7 consists of an unchanging memory 43 in which are stored unchanging parameters and arranged in libraries function modules of the bottom layer 2, middle layer 12 and application programs of the top layer 22. A non-volatile memory 44 contains application programs and recently loaded software components of the firmware. The microprocessor 23 uses not only memories 43 to 44, but also a volatile memory defined as a working memory 45. The memory system can be accessed in software terms by the software component memory interface 7 and complemented with additional memory capacity by a memory extension interface 46.

In the non-volatile memory 44 are stored recently loaded application programs 21 and software components. For the software components of layers 12 and 2, tabular references indicate the current software components. If the software component has never been exchanged, it is located in the unchanging memory 43 or in the non-volatile memory 44.

A main task of the memory interface 7 is the administration of references and variables of the program.

If a measurement value of a transponder is to be determined, this is triggered in the application program 21 by the call of the corresponding function e.g. monitoring module 13 which is made available via the application interface 20. When the address table of the non-volatile memory 44 is used, it can be established where the current software component of the monitoring unit 13 is located and the corresponding operation of this software component can be executed. For this purpose, the measurement data interface 4 of the bottom layer 2 is used. Here too the current software component is determined via the corresponding table of the non-volatile memory 44 and the read-out of the measurement value is triggered.

1. A transponder with firmware
which firmware comprise several overlaid layers (2, 12, 22) containing several software components known as function modules (3 to 11, 13 to 19),
where a bottom layer (2) contains the function modules (3 to 11) which describe the functionality of the hardware components of the transponder,
and the function modules (13 to 19) of the layer (12) lying above the bottom layer (2) jointly form an application interface which can process an application software of various manufacturer-dependent central monitoring systems, and hence the same transponder can be used in different monitoring systems with different protocols and management purposes.

2. A transponder as claimed in claim 1, characterized in that a network element belonging to the transponder is a network element of a hybrid fiber coax (HFC) network.

3. A transponder as claimed in claim 1, characterized in that the function modules (13 to 19) of the layer (12) lying over the bottom layer (2) are provided for access to the other function modules (3 to 11, 13 to 19) of the same layer and the bottom layer (2).

4. A transponder as claimed in claim 3, characterized in that the upper layer (22) is provided for access by a supplier of the central monitoring system and for the downloading of new application programs by the supplier of the central monitoring system, and in that the bottom layer (2) and the layer (12) lying over the bottom layer (2) are provided for access by the transponder manufacturer and for the downloading of function modules (3 to 11, 13 to 19) by the transponder manufacturer.

5. A transponder as claimed in claim 4, characterized in that hardware (1) forming the basis of the transponder is intended for exchange while the layer (12) lying over the lower layer (2) and the upper layer (22) can remain unchanged.
